(19) United States
(12) Patent Application Publication
(10) Pub. No.: US 2024/0268098 A1
(43) Pub. Date: Aug. 8, 2024

(54) SEMICONDUCTOR DEVICES

(71) Applicant: SAMSUNG ELECTRONICS CO., LTD., Suwon-si (KR)

(72) Inventors: Junsoo KIM, Suwon-si (KR); Dongsik KONG, Suwon-si (KR); Jihye KWON, Suwon-si (KR); Junbum LEE, Suwon-si (KR); Sungho JANG, Suwon-si (KR)

(21) Appl. No.: 18/510,949

(22) Filed: Nov. 16, 2023

(30) Foreign Application Priority Data
Feb. 7, 2023 (KR) 10-2023-0016040

(51) Int. Cl. H10B 12/00; H01L 29/66; H01L 29/78

(52) U.S. Cl. CPC H10B 12/315; H01L 29/66666; H01L 29/7827; H10B 12/053; H10B 12/34

(57) ABSTRACT

A semiconductor device includes a first active pattern protruding from a substrate; a gate structure including a gate insulation layer and a gate pattern laterally stacked on a first sidewall of the first active pattern, the gate pattern facing the first sidewall of the first active pattern and extending a first direction parallel to an upper surface of the substrate; and first conductive patterns contacting the gate insulation layer and protruding from a sidewall of the gate structure. The first conductive patterns may be disposed to face second and third sidewalls in the first direction of the first active pattern, and first conductive patterns may be spaced apart from the first active pattern.

### CROSS-REFERENCE TO RELATED APPLICATION

This application claims priority under 35 USC § 119 to Korean Patent Application No. 10-2023-0016040, filed on Feb. 7, 2023, in the Korean Intellectual Property Office (KIPO), the contents of which are incorporated by reference herein in their entirety.

### BACKGROUND

### 1. Field

Example embodiments relates to semiconductor devices. Particularly, example embodiments relate to a semiconductor device including a vertical channel transistor.

### 2. Description of the Related Art

A semiconductor device may include vertical channel transistors. Each of the vertical channel transistors may include an active pattern having a pillar shape and a gate structure on one sidewall of the active pattern.

### SUMMARY

According to example embodiments, there is provided a semiconductor device. The semiconductor device may include a first active pattern protruding from a substrate; a gate structure including a gate insulation layer and a gate pattern laterally stacked on a first sidewall of the first active pattern, the gate pattern facing the first sidewall of the first active pattern and extending a first direction parallel to an upper surface of the substrate; and first conductive patterns contacting the gate insulation layer and protruding from a sidewall of the gate structure. The first conductive patterns may be disposed to face second and third sidewalls in the first direction of the first active pattern, and first conductive patterns may be spaced apart from the first active pattern.

According to example embodiments, there is provided a semiconductor device. The semiconductor device may include a first active patterns protruding from a substrate, a plurality of first active patterns arranged in first and a second directions parallel to an upper surface of the substrate and perpendicular to each other, and the first active patterns being spaced apart from each other; a gate structure on first sidewalls of the first active patterns, the gate structure extending in the second direction to face the first sidewalls of the first active patterns; a separation pattern filling an opening between second sidewalls facing the first sidewall of the first active pattern; and a conductive liner structure protruding from a sidewall of the gate structure, the conductive liner structure being spaced apart from the first active pattern, and disposed to face each of third and fourth sidewalls in the second direction of the first active pattern. The conductive liner structure may include first conductive layer patterns disposed to face the third and fourth sidewalls of each of the first active patterns, and being spaced apart from the first active patterns, and a second conductive layer pattern electrically connected to lower portions of the first conductive layer patterns to each other.

According to example embodiments, there is provided a semiconductor device. The semiconductor device may include first active patterns protruding from a substrate, the first active patterns arranged in first and a second directions parallel to an upper surface of the substrate and perpendicular to each other, and the first active patterns being spaced apart from each other; a gate structure on first sidewalls of the first active patterns, the gate structure extending in the second direction to face the first sidewalls of the first active patterns, and the gate structure including a gate insulation layer and a gate pattern; and a conductive liner structure disposed to face each of second and third sidewalls in the second direction of the first active patterns. The conductive liner structure may be spaced apart from the gate pattern and the first active pattern.

### BRIEF DESCRIPTION OF THE DRAWINGS

Features will become apparent to those of skill in the art by describing in detail exemplary embodiments with reference to the attached drawings, in which:

FIGS. 1 to 3 are a plan view and cross-sectional views illustrating a semiconductor device according to example embodiments;

FIG. 4 is a perspective view of a portion of the semiconductor device;

FIG. 5 is a plan view illustrating a conductive liner structure in the semiconductor device;

FIGS. 6 and 7 are a plan view and a cross-sectional view illustrating a semiconductor device according to example embodiments;

FIGS. 8 and 9 are a plan view and a cross-sectional view illustrating a semiconductor device according to example embodiments;

FIGS. 10 to 28 are plan views and cross-sectional views illustrating stages in a method of manufacturing a transistor according to example embodiments;

FIG. 29 is a perspective view illustrating a semiconductor device according to example embodiments; and

FIGS. 30 to 33 are perspective views illustrating stages in a method of manufacturing a semiconductor device according to example embodiments.

### DETAILED DESCRIPTION OF THE EMBODIMENTS

Hereinafter, preferred embodiments will be described in detail with reference to the accompanying drawings.

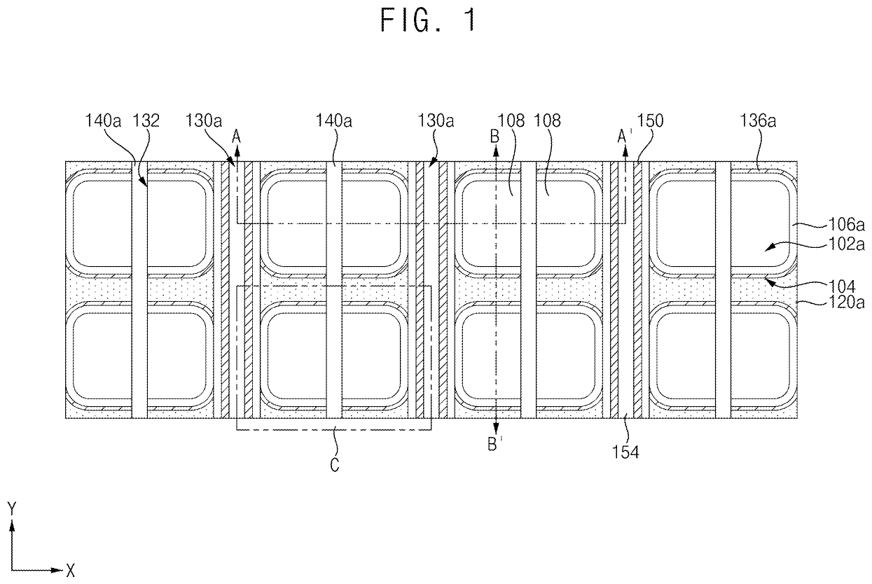

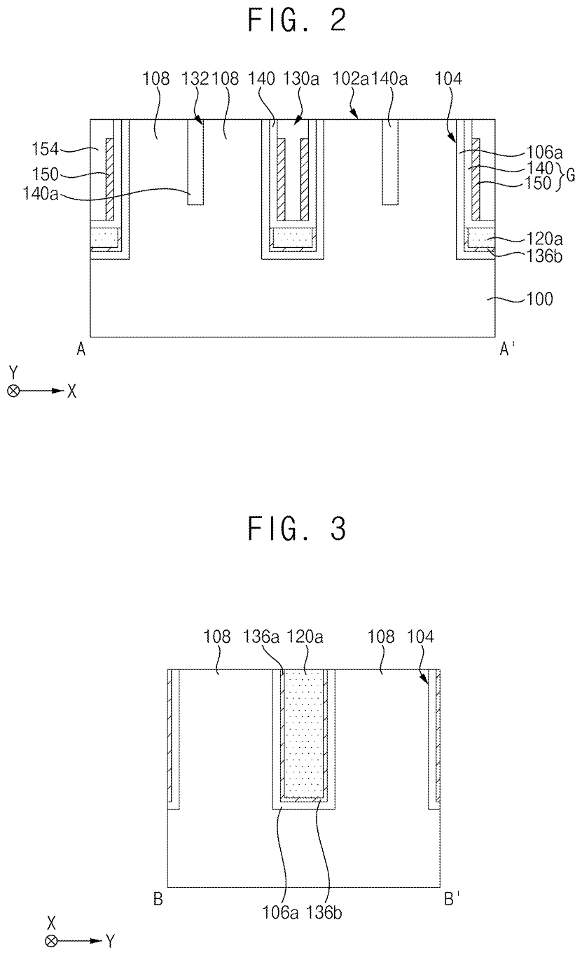

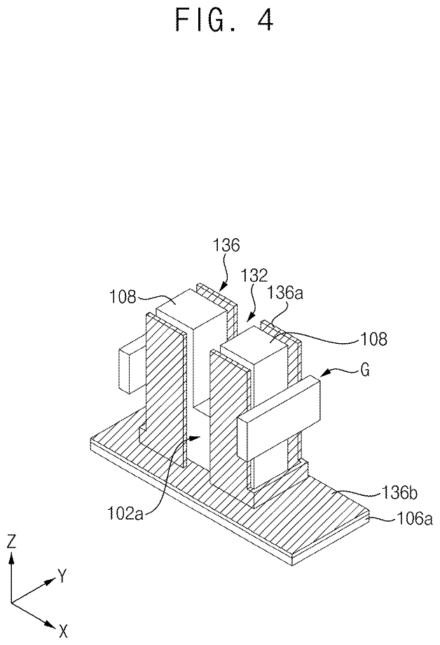

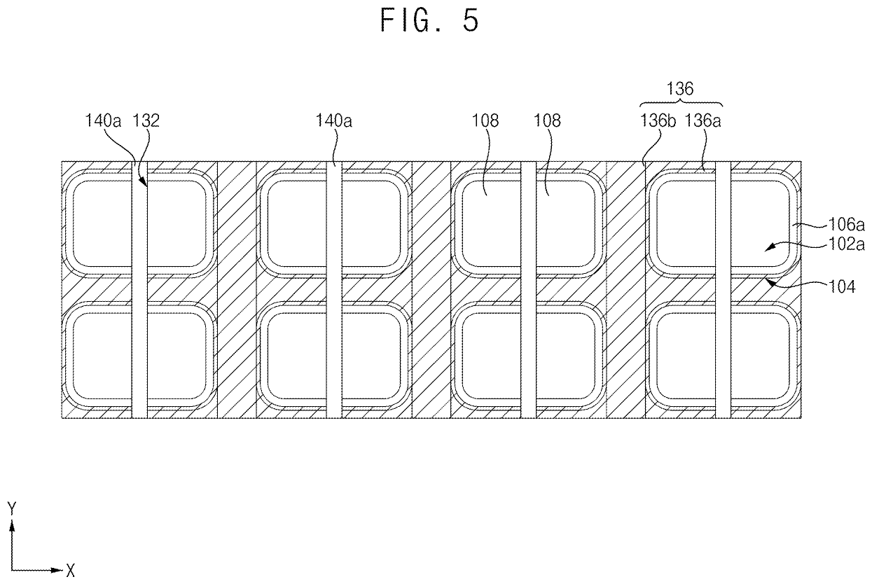

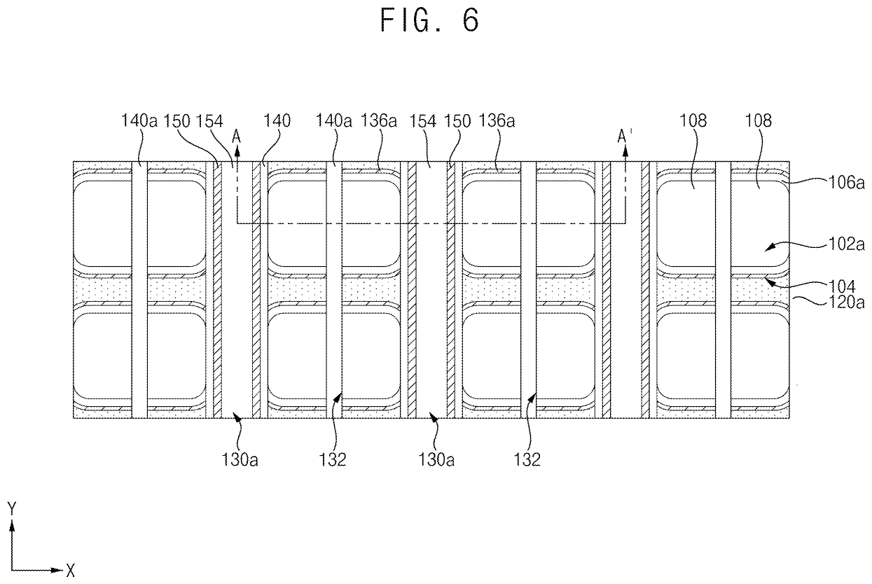

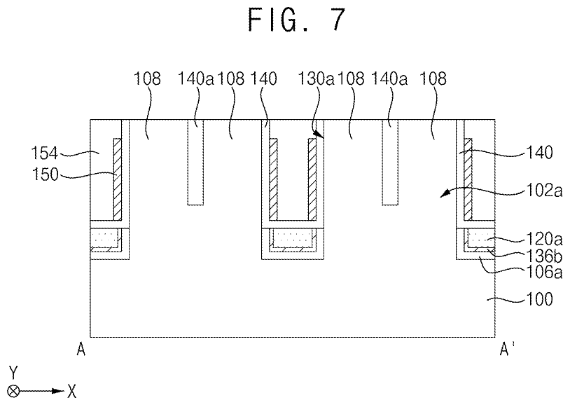

FIG. 1 is a plan view of a semiconductor device according to example embodiments. FIG. 2 is a cross-sectional view taken along line A-A′ of FIG. 1, and FIG. 3 is a cross-sectional view taken along line B-B′ of FIG. 1. FIG. 4 is a perspective view of portion C of FIG. 1. FIG. 5 is a plan view illustrating a conductive liner structure in the semiconductor device of FIG. 1. FIG. 6 is a plan view of a semiconductor device according to example embodiments, and FIG. 7 is a cross-sectional view taken along line A-A′ of FIG. 6.

Referring to FIGS. 1 to 5, a substrate 100 may be provided. The substrate 100 may include a semiconductor material, e.g., silicon, germanium, or silicon-germanium, or a III-V compound semiconductor, e.g., GaP, GaAs, or GaSb. In some example embodiments, the substrate 100 may be a silicon-on-insulator (SOI) substrate or a germanium-on-insulator (GOI) substrate.

A first trench 104 may be disposed on the substrate 100. A portion of the substrate 100 between portions of the first trench 104 may be defined as an active structure 102a. The first trench 104 may extend in a first direction X and a second direction Y, respectively. For example, referring to FIG. 1, the first trench 104 may extend continuously in a grid pattern in the first and second directions X and Y, and a plurality of the active structures 102a may be arranged in a matrix pattern between portions of the first trench 104, e.g., so each of the active structures 102a may be surrounded by portions of the first trench 104 (e.g., as viewed in a top view). The first and second directions X and Y may be parallel to an upper surface of the substrate 100, and may be perpendicular to each other.

A second opening 132 may be formed at an upper portion of the active structure 102a, and the second opening 132 may extend, e.g., lengthwise, in the second direction Y. The second opening 132 may be formed to cross a center portion in the first direction X of the active structure 102a, and first active patterns 108 may be disposed at both sides of the second opening 132. That is, one active structure 102a may include two first active patterns 108 spaced apart from each other in the first direction X by the second opening 132. In example embodiments, a bottom of the first trench 104 may be lower than a bottom of the second opening 132, e.g., relative to a bottom of the substrate 100.

Each of the first active patterns 108 may have a pillar shape. The first active patterns 108 may protrude upwardly from the substrate 100. The first active patterns 108 may be symmetrical with respect to the second opening 132. The first active patterns 108 may be spaced apart from each other in the first and second directions X and Y.

As illustrated in FIG. 1, the active structures 102a may be regularly arranged in the first and second directions X and Y. The first active patterns 108 may be disposed parallel to each other in the first direction X, and may be disposed parallel to each other in the second direction Y.

A third insulation layer may fill the second opening 132. The third insulation layer may include, e.g., silicon oxide. The third insulation layer filling the second opening 132 may serve as a separation layer pattern 140a.

The first active pattern 108 may include a first sidewall and a second sidewall facing each other in the first direction X. The second sidewall of the first active pattern 108 may, e.g., directly, contact the separation layer pattern 140a.

As illustrated in FIG. 4, a gate structure G may be disposed on the first sidewall of the first active pattern 108. As illustrated in FIG. 2, the gate structure G may include a gate insulation layer 140 and a gate pattern 150 laterally stacked on the first sidewall of the first active pattern 108, e.g., the gate structure G and the separation layer pattern 140a may be on opposite sidewalls of the first active pattern 108. The gate insulation layer 140 may include the third insulation layer, and thus, the gate insulation layer 140 may include a same material as a material of the separation layer pattern 140a.

As illustrated in FIGS. 1 and 2, a first opening 130a extending, e.g., lengthwise, in the second direction Y may be disposed between the active structures 102a spaced apart from each other in the first direction X, and the gate structure G may be disposed in the first opening 130a. The first opening 130a may overlap a portion of the first trench 104.

Gate patterns 150 separated from each other may be formed on both sidewalls of the first opening 130a, respectively. That is, two gate structures G may be formed in one first opening 130a, e.g., the two gate structures G may be formed on opposite sidewalls of a same first opening 130a.

A top surface of the gate pattern 150 may be lower than a top surface of the first active pattern 108, .g., relative to a bottom of the substrate 100. A filling insulation pattern 154 may fill a space between the gate patterns 150 in the same first opening 130a.

The gate structure G may extend in the second direction Y so as to face the first sidewalls of the plurality of first active patterns 108 arranged in the second direction Y. The gate pattern 150 may serve as a word line.

A second insulation layer pattern 120a may extend in the second direction Y. A portion of the second insulation layer pattern 120a may be disposed under a bottom of the gate structure G in the first opening 130a. A second conductive layer pattern 136b may surround a sidewall and a bottom of the second insulation layer pattern 120a.

For example, as shown in FIGS. 1 and 2, a first insulation layer pattern 106a, the second insulation layer pattern 120a, the second conductive layer pattern 136b, the third insulation layer 140, and the gate pattern 150 may be formed in the first opening 130a. The first insulation layer pattern 106a may, e.g., continuously, cover the first sidewall of the first active pattern 108 and the bottom of the first trench 104. The second insulation layer pattern 120a may be formed on the first insulation layer pattern 106a in a lower portion the first opening 130a, and the second conductive layer pattern 136b may separate between the first insulation layer pattern 106a and the second insulation layer pattern 120a. The third insulation layer 140 may be formed, e.g., continuously, on the first insulation layer pattern 106a, the second insulation layer pattern 120a, and the second conductive layer pattern 136b, e.g., the third insulation layer 140 may be directly on a portion of the first insulation layer pattern 106a. The gate pattern 150 may be formed on the third insulation layer 140. In this case, the first insulation layer pattern 106a, the third insulation layer 140, and the gate pattern 150 may be stacked on the first sidewall of the first active pattern 108. Thus, the first insulation layer pattern 106a and the third insulation layer 140 may serve together as a gate insulation layer.

In another example, as shown in FIGS. 6 and 7, the first insulation layer pattern 106a, the second insulation layer pattern 120a, the second conductive layer pattern 136b, the third insulation layer 140, and the gate pattern 150 may be formed in the first opening 130a. The first insulation layer pattern 106a, the second conductive layer pattern 136b, and the second insulation layer pattern 120a may be positioned in a lower portion of the first opening 130a. The first insulation layer pattern 106a may be formed on (e.g., only on) a lower portion of the first sidewall of the first active pattern 108 and a bottom of the first trench 104. The second insulation layer pattern 120a may be formed on the first insulation layer pattern 106a in the lower portion of the first opening 130a. The third insulation layer 140 may be formed on (e.g., directly on) the first sidewall of the first active pattern 108 and upper surfaces of the first insulation layer pattern 106a, the second insulation layer pattern 120a, and the second conductive layer pattern 136b. The gate pattern 150 may be formed on the third insulation layer 140. In this case, the third insulation layer 140 and the gate pattern 150 may be stacked on the first sidewall of the first active pattern 108. Therefore, the third insulation layer 140 may serve as a gate insulation layer.

The first insulation layer pattern 106a may be formed on the third and fourth sidewalls of the first active pattern 108 facing each other in the second direction Y. In addition, a conductive liner structure 136 may be spaced apart from the third and fourth sidewalls of the first active pattern 108, and a portion of the conductive liner structure 136 may face the third and fourth sidewalls of the first active pattern 108. The conductive liner structure 136 may include the first conductive layer pattern 136a and the second conductive layer pattern 136b. As illustrated in FIG. 4, the first conductive layer pattern 136a may be disposed on the third and fourth sidewalls of the first active pattern 108. Other portion of the conductive liner structure 136 other than the first conductive layer pattern 136a may be the second conductive layer pattern 136b. The second conductive layer pattern 136b may be connected to lower portions of the first conductive layer patterns 136a.

As illustrated in FIG. 3, the first conductive layer pattern 136a may be laterally stacked on the first insulation layer pattern 106a, and thus, the first insulation layer pattern 106a and the first conductive layer pattern 136a may cover the third and fourth sidewalls of the active pattern 108. As illustrated in FIG. 5, the first insulation layer pattern 106a may be interposed between the first conductive layer pattern 136a and the first active pattern 108. The first conductive layer pattern 136a may not contact the gate pattern 150. Accordingly, the first conductive layer pattern 136a may be spaced apart from the gate pattern 150, and may not be electrically connected to the gate pattern 150.

As illustrated in FIG. 4, a top surface of the first conductive layer pattern 136a covering the third and fourth sidewalls of the first active pattern 108 may be higher than a top of the gate pattern 150, e.g., relative to the bottom of the substrate 100. The first conductive layer pattern 136a may protrude from (e.g., beyond) one sidewall of the gate structure G in the first direction X while contacting the gate insulation layer of the gate structure G (FIG. 1).

Referring to FIGS. 2 and 4, the second conductive layer pattern 136b may be disposed on the bottom of the first trench 104 and a lower sidewall of the first active pattern 108 at a lower portion of the first opening 130a. The first insulation layer pattern 106a may be interposed between the second conductive layer pattern 136b and the bottom of the first trench 104 and between the second conductive layer pattern 136b and the lower sidewall of the first active pattern 108 at the lower portion of the first opening 130a. The second conductive layer pattern 136b may not be electrically connected to the gate pattern 150.

Therefore, the first conductive layer pattern 136a and the second conductive layer pattern 136b included in the conductive liner structure 136 may be electrically connected to each other. However, the conductive liner structure 136 may not be electrically connected to the gate pattern 150.

Since the first and second conductive layer patterns 136a and 136b are formed by the same deposition process, the first and second conductive layer patterns 136a and 136b may be one body including, e.g., consisting of, the same conductive material. For example, referring to FIG. 5, the first and second conductive layer patterns 136a and 136b may be integral with each other, e.g., formed into a single and seamless body. The first and second conductive layer patterns 136a and 136b may include, e.g., titanium, titanium nitride, tantalum, tantalum nitride, tungsten, tungsten nitride, tungsten carbonitride, or the like.

The first conductive layer patterns 136a facing the third and fourth sidewalls of the first active patterns 108 may be electrically connected to each other by the second conductive layer pattern 136b. Electrical signals may apply through the second conductive layer pattern 136b, and thus, the electrical signal may be applied to the plurality of first conductive layer patterns 136a.

The conductive liner structure 136 may induce electric fields in the first active pattern 108 so that a threshold voltage of the vertical channel transistor may be controlled by inducing electric fields in the first active pattern 108. Therefore, a thickness of the conductive liner structure 136 may not be limited. For high integration of the vertical channel transistor, the thickness of the conductive liner structure 136 (i.e., the thickness in a vertical direction from an underlying layer) may be thin. In example embodiments, the conductive liner structure 136 may have a thickness of about 10 angstroms to about 100 angstroms, e.g., about 20 angstroms to about 30 angstroms.

The second insulation layer pattern 120a may be formed on the first and second conductive layer patterns 136a and 136b in the first trench 104 between the active structures 102a in the second direction Y. The second insulation layer pattern 120a may fill the first trench 104 between the active structures 102a in the second direction Y.

In example embodiments, the first insulation layer pattern 106a, the second insulation layer pattern 120a, and the third insulation layer 140 may include silicon oxide. The first insulation layer pattern 106a, the second insulation layer pattern 120a, and the third insulation layer 140 may include the same material, so that the first insulation layer pattern 106a, the second insulation layer pattern 120a, and the third insulation layer 140 may be merged into one layer.

A lower portion of the first active pattern 108 may serve as a first source/drain region, and an upper portion of the first active pattern 108 may serve as a second source/drain region. The first active pattern 108 between the first and second source/drain regions may serve as a channel region. A surface of the first active pattern 108 facing the gate pattern 150 may serve as the channel region. Accordingly, referring to FIGS. 2 and 4, the first active pattern 108, the gate insulation layer 140, and the gate pattern 150 may serve as the vertical channel transistor. A plurality of vertical channel transistors may be formed on sidewalls of the first active patterns 108 arranged in the second direction Y, and the vertical channel transistors may use the gate pattern 150 as a word line.

As described above, referring to FIGS. 2-4, the plurality of vertical channel transistors may further include the first conductive layer pattern 136a. The first insulation layer pattern 106a and the first conductive layer pattern 136a may be disposed to face the third and fourth sidewalls, which are both sidewalls in the second direction Y, of the first active pattern 108. As such, the first conductive layer pattern 136a may partially surround the first active pattern 108 to be spaced apart from the first active pattern 108.

The first conductive layer pattern 136a may have a function similar to that of a back gate electrode included in the first active pattern 108. When the voltage is applied to the first conductive layer pattern 136a via the second conductive layer pattern 136b, a body voltage (e.g., channel body voltage) may be applied to a portion facing sidewalls of the first active patterns 108 of the plurality of vertical channel transistors. Since the conductive liner structure 136 is not electrically connected to the gate pattern 150, voltages may be independently applied to the first conductive layer pattern 136a and the gate pattern 150. In example embodiments, the voltage applied to the first conductive layer pattern 136a and the voltage applied to the gate pattern 150 may be different from each other. The threshold voltage of the vertical channel transistor may be controlled according to the voltage applied to the first conductive layer pattern 136a.

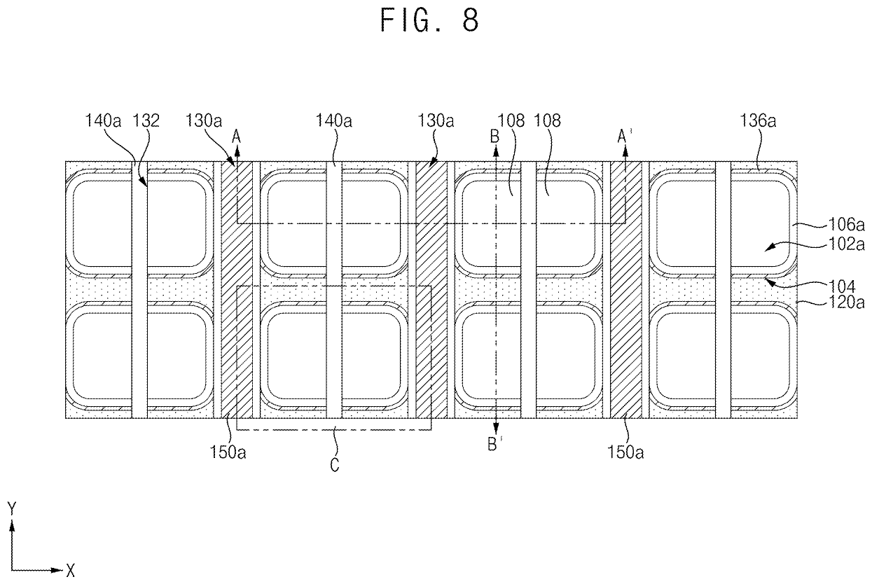

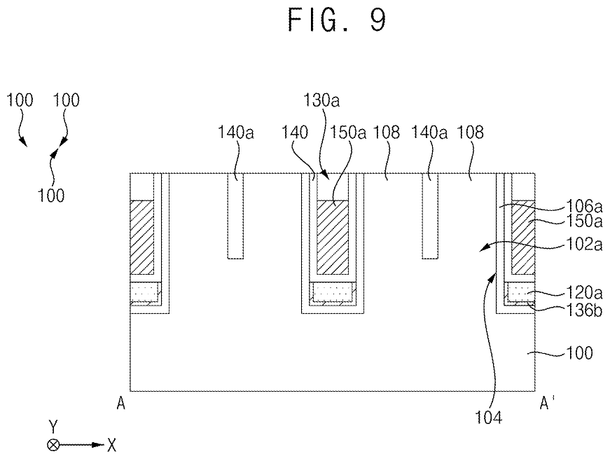

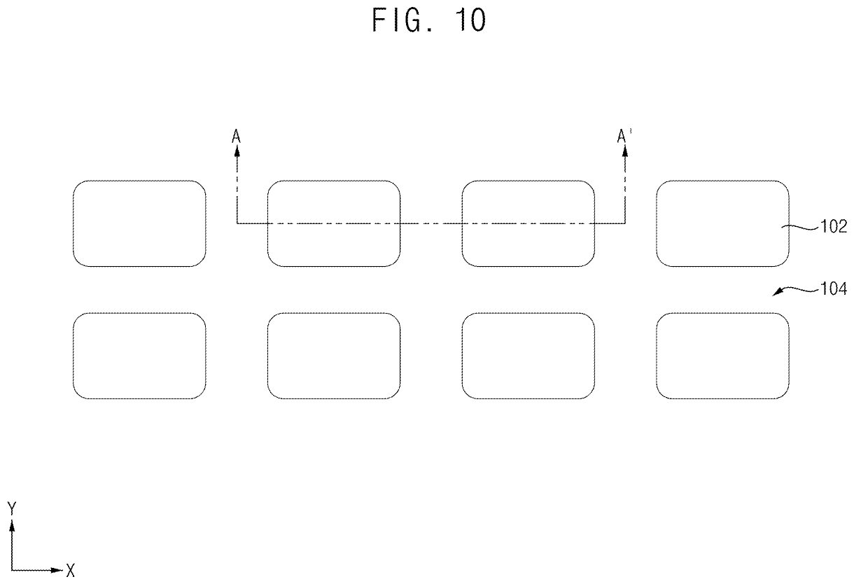

FIGS. 8 and 9 are a plan view and a cross-sectional view illustrating a semiconductor device according to example embodiments. The semiconductor device shown in FIGS. 8 and 9 is substantially the same as the semiconductor device described with reference to FIGS. 1 to 5, except for a shape of a gate pattern.

Referring to FIGS. 8 and 9, a gate structure may be disposed on the first sidewall of the first active pattern 108. The gate structure may include a gate insulation layer and a gate pattern 150a stacked laterally from the first sidewall of the first active pattern 108.

The first opening 130a extending in the second direction Y may be positioned between the first active patterns 108 spaced apart from each other in the first direction X. The gate structure may be disposed at an inner portion of the first opening 130a. The first opening 130a may overlap a portion of the first trench 104.

One gate pattern 150a may be formed in the first opening 130a. That is, a single gate pattern 150a may be formed between the active structures 102a spaced apart from each other in the first direction X. Accordingly, the two first active patterns 108 disposed on both sides of the one gate pattern 150a may be controlled by the one gate pattern 150a. A top surface of the gate pattern 150a may be lower than a top surface of the first active pattern 108.

A lower portion of the first active pattern 108 may serve as the first source/drain region, and an upper portion of the first active pattern 108 may serve as the second source/drain region. The first active pattern 108 between the first and second source/drain regions may serve as the channel region. A surface of the first active pattern 108 facing the gate pattern 150a may serve as the channel region. Accordingly, the two first active patterns 108, and the gate insulation layer and the gate pattern 150 formed between the two first active patterns 108 may serve as one vertical channel transistor.

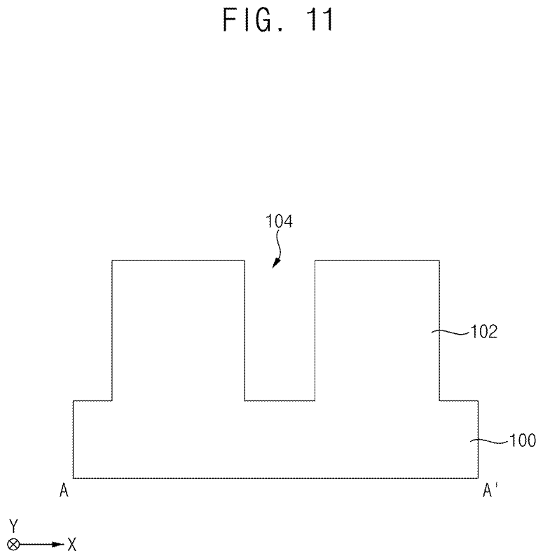

FIGS. 10 to 28 are plan views and cross-sectional views of stages in a method of manufacturing a transistor according to example embodiments. FIGS. 10, 12, 14, 16, 18, 20, 22, 24 and 26 are plan views, and FIGS. 11, 13, 15, 19, 21, 23, 25, 27, and 28 are cross-sectional views along line A-A′ of corresponding ones of the plan views.

Referring to FIGS. 10 and 11, a portion of the substrate 100 may be etched to form the first trench 104 and preliminary active structures 102. The preliminary active structures 102 may correspond to protruding portions between portions of the first trench 104.

Each of the preliminary active structures 102 may have a pillar shape. In example embodiments, the preliminary active structures 102 may have a length in the first direction X greater than a length in the second direction Y. A longitudinal direction of the preliminary active structures 102 may be the first direction X. The preliminary active structures 102 may be spaced apart from each other in the first direction X and the second direction Y. The preliminary active structures 102 may be disposed parallel to each other in the first direction X, and may be disposed parallel to each other in the second direction Y. Accordingly, the first trench 104 may extend in the first direction X and the second direction Y, respectively.

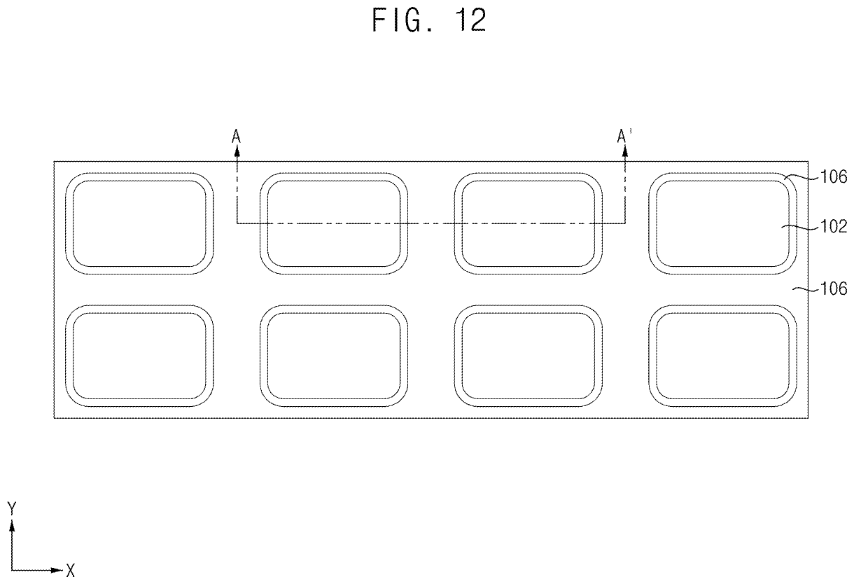

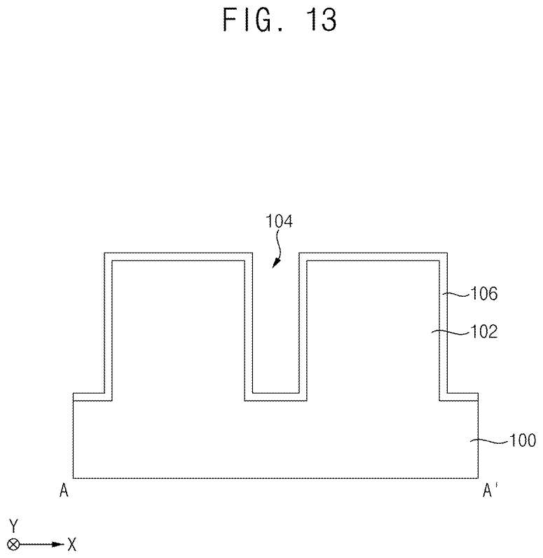

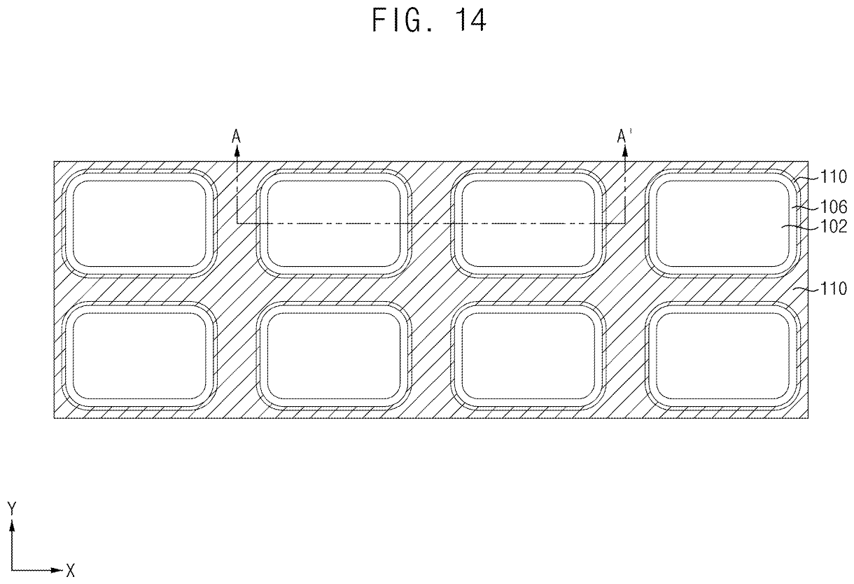

Referring to FIGS. 12 and 13, a first insulation layer 106 may be formed on surfaces of the preliminary active structures 102 and the first trench 104. The first insulation layer 106 may include, e.g., silicon oxide. In example embodiments, the first insulation layer 106 may be formed by an atomic layer deposition process.

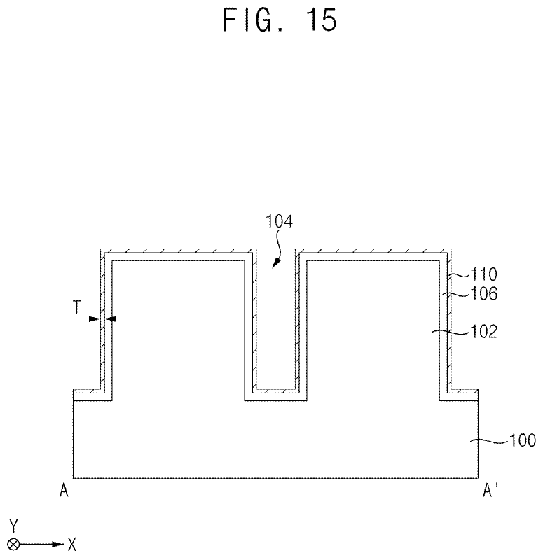

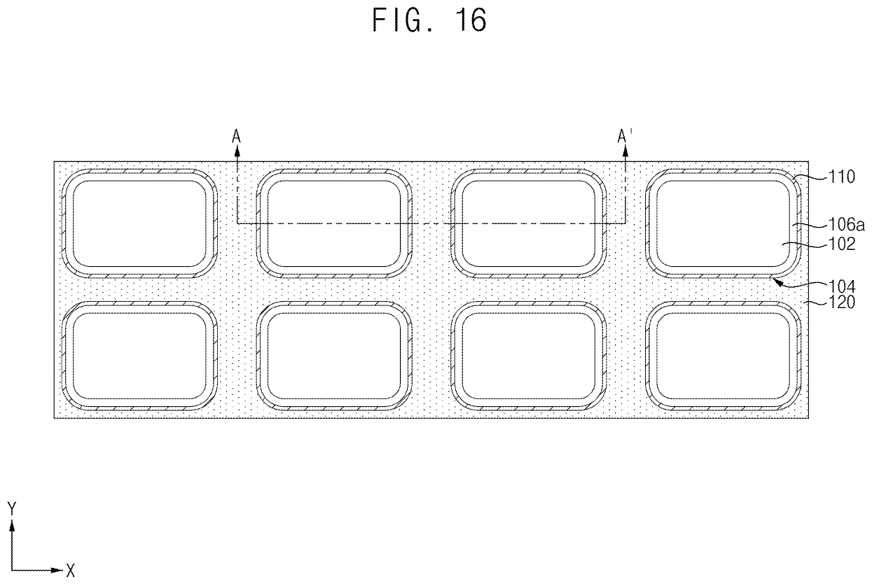

Referring to FIGS. 14 and 15, a first conductive layer 110 may be formed on the, e.g., entire, surface of the first insulation layer 106. The first insulation layer 106 and the first conductive layer 110 may be conformally, e.g., and continuously, formed along surface profiles of the first trench 104 and the preliminary active structures 102. After forming the first conductive layer 110, an inner space of the first trench 104 may remain.

The first conductive layer 110 may include, e.g., titanium, titanium nitride, tantalum, tantalum nitride, tungsten, tungsten nitride, tungsten carbonitride, or the like. In example embodiments, the first conductive layer 110 may be formed by an atomic layer deposition process.

In example embodiments, the first conductive layer 110 may have a thickness T of about 10 angstroms to about 100 angstroms, e.g., about 20 angstroms to about 30 angstroms. The thickness T of the first conductive layer 110 may be measured from a surface of the first insulation layer 106 along a direction normal to the surface of the first insulation layer 106 at the measuring point.

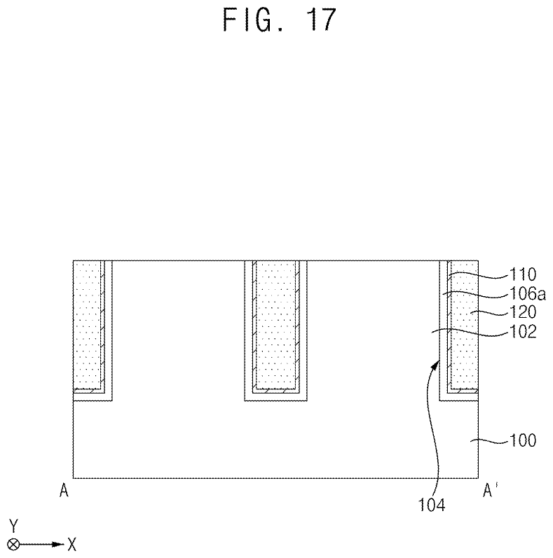

Referring to FIGS. 16 and 17, a second insulation layer 120 may be formed on the first insulation layer 106 and the first conductive layer 110 to completely fill the first trench 104. The second insulation layer 120 may include, e.g., silicon oxide. Thereafter, an upper surface of the second insulation layer 120 may be planarized until an upper surface of the preliminary active structure 102 is exposed. The planarization process may include, e.g., a chemical mechanical polishing process and/or an etch-back process.

By the planarization process, the first conductive layer 110 and the first insulation layer 106 formed on the upper surface of the preliminary active structure 102 may be removed, and the upper surface of the preliminary active structure 102 may be exposed. Also, the first insulation layer pattern 106a may be formed by removing a portion of the first insulation layer 106.

The first insulation layer pattern 106a, the first conductive layer 110, and the second insulation layer 120 may fill the first trench 104. The first insulation layer pattern 106a and the first conductive layer 110 may be conformally formed on a sidewall and a bottom of the first trench 104.

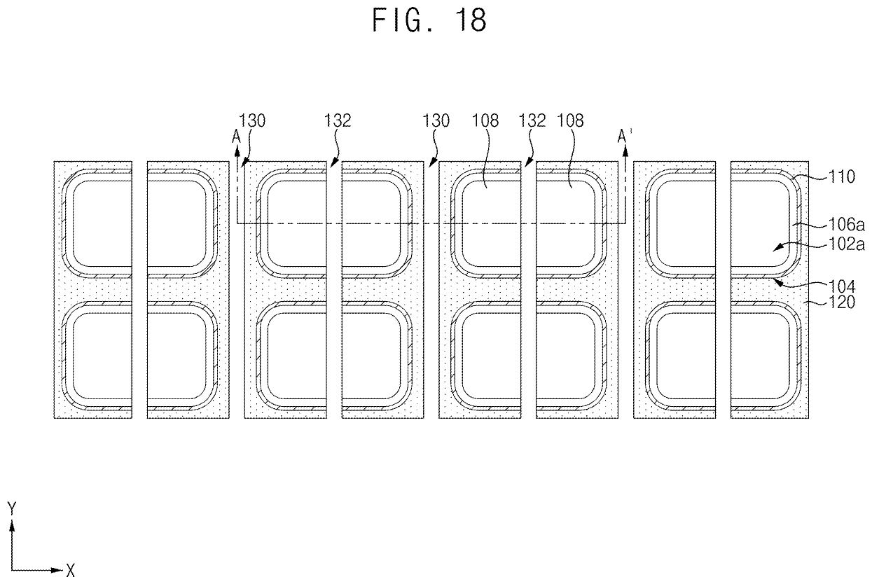

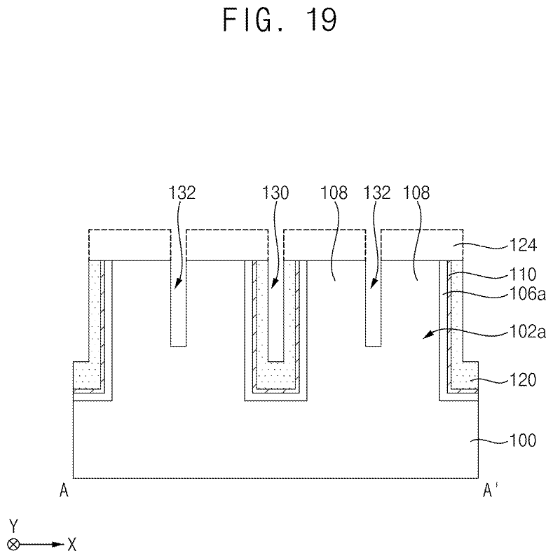

Referring to FIGS. 18 and 19, a first hard mask layer may be formed on the preliminary active structure 102, the first conductive layer 110, the first insulation layer pattern 106a, and the second insulation layer 120. A first hard mask pattern 124 may be formed by patterning the first hard mask layer.

The first hard mask pattern 124 may include an opening exposing a region for forming a gate structure and an opening exposing a cutting portion of the preliminary active structure 102. The openings may extend in the second direction Y.

The opening exposing a region for forming the gate structure may expose the second insulation layer 120 in the first trench 104 between the preliminary active structures 102 in the first direction X. The opening exposing the cutting portion of the preliminary active structure 102 may be disposed to cross a center portion in the first direction X of each of the preliminary active structures 102.

The second insulation layer 120 and the preliminary active structure 102 may be anisotropically etched using the first hard mask pattern 124 as an etch mask to form a preliminary first opening 130 and the second opening 132. The preliminary first opening 130 may be positioned at the region for forming the gate structure, and the second opening 132 may be positioned on the preliminary active structure 102. The preliminary active structure 102 may be separated by the second opening 132 to form the active structure 102a including two first active patterns 108.

The preliminary first openings 130 and the second openings 132 may be alternately and repeatedly disposed in the first direction X. The active structure 102a may be disposed between the preliminary first openings 130.

In the etching process, the first active pattern 108 and the second insulation layer 120 including different materials to each other may be simultaneously etched. For example, the first active pattern 108 including silicon and the second insulation layer 120 including silicon oxide may be simultaneously etched. In the etching process, an etching rate of the first active pattern 108 and an etching rate of the second insulation layer 120 may be different from each other. Accordingly, the preliminary first opening 130 and the second opening 132 may have different depths to each other. In example embodiments, the etching rate of the first active pattern 108 may be lower than the etching rate of the second insulation layer 120. Accordingly, a depth of the preliminary first opening 130 may be greater than a depth of the second opening 132.

In example embodiments, a width of the second opening 132 may be less than twice a target thickness of an insulation layer (e.g., a third insulation layer) serving as a gate insulation layer in subsequent processes. In example embodiments, the preliminary first opening 130 and the second opening 132 may have substantially the same width.

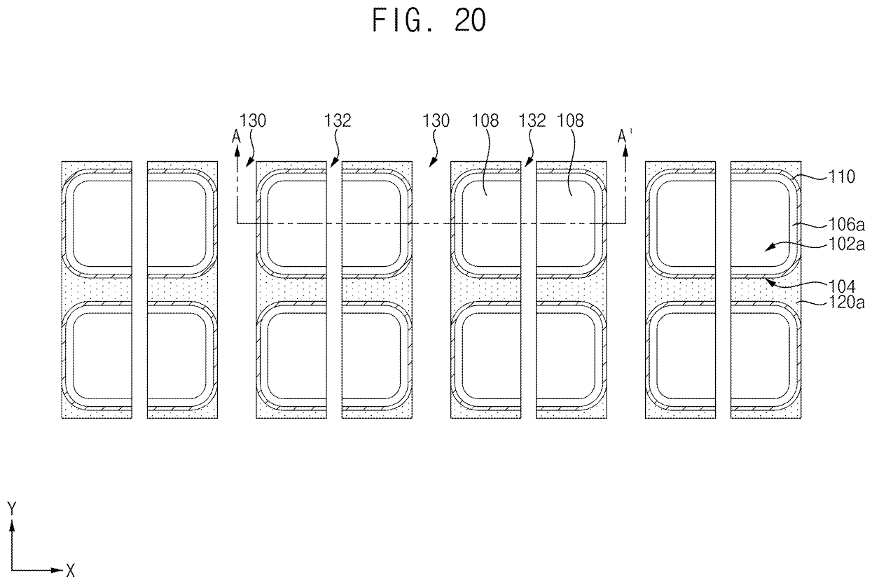

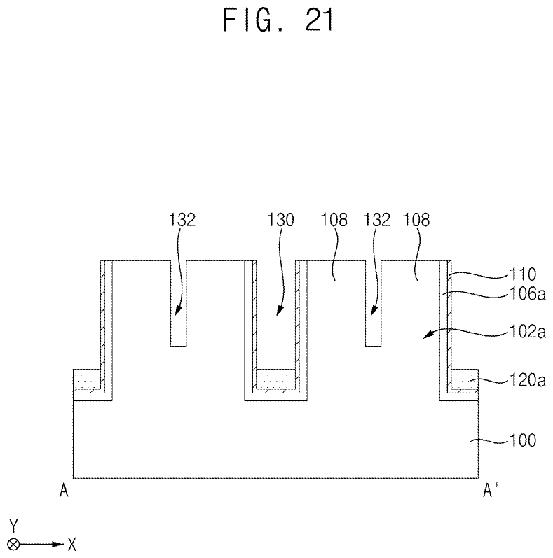

Referring to FIGS. 20 and 21, the second insulation layer 120 in the preliminary first opening 130 may be partially etched to form the second insulation layer pattern 120a. In the etching process, the second insulation layer 120 formed on the sidewall of the preliminary first opening 130 may be completely removed. The first conductive layer 110 may be exposed by the sidewall of the preliminary first opening 130. Accordingly, the width of the preliminary first opening 130 may be increased. The second insulation layer pattern 120a may be formed in a lower portion of the preliminary first opening 130.

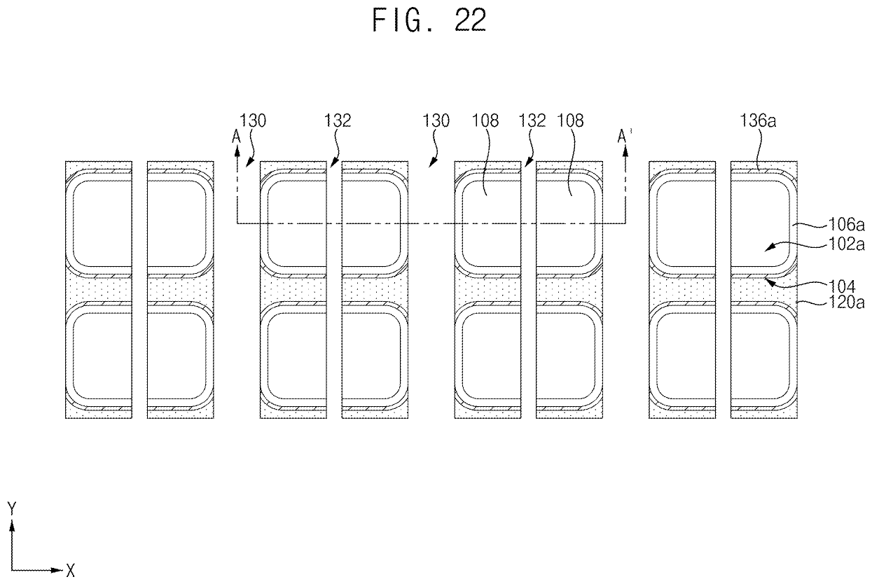

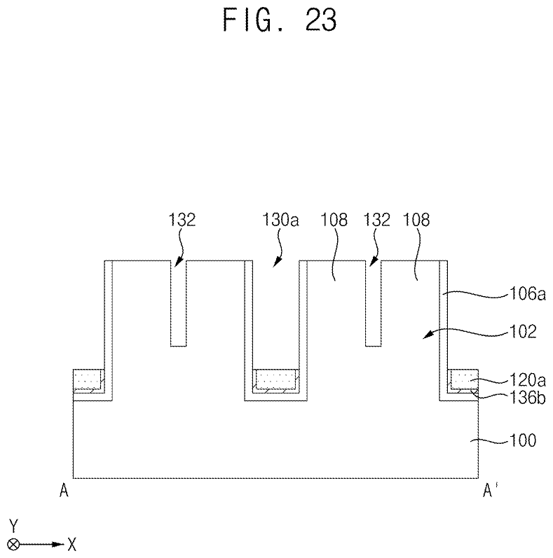

Referring to FIGS. 22 and 23, the first conductive layer 110 exposed on the sidewall of the preliminary first opening 130 may be removed to form the first opening 130a and a conductive liner structure.

A width of the first opening 130a may be greater than a width of the second opening 132. Also, the depth of the first opening 130a may be greater than the depth of the second opening 132. The first insulation layer pattern 106a may remain on the surface of the first trench 104. The first insulation layer pattern 106a may be exposed on the sidewall of the first opening 130a.

The conductive liner structure 136 may include first and second conductive layer patterns 136a and 136b. The conductive liner structure 136 may be referred to as the first conductive layer pattern 136a or the second conductive layer pattern 136b (referred to FIGS. 4 and 5) depending on positions thereof.

The first conductive layer pattern 136a may be spaced apart from both sidewalls (hereinafter referred to as third and fourth sidewalls) of the first active patterns 108 in the second direction Y, and the first active patterns 108 may be disposed to face the third and fourth sidewalls.

The second conductive layer pattern 136b may be disposed on a bottom of the first trench 104 and on a lower sidewall of the first active pattern 108 in a lower portion of the first opening 130a. The second conductive layer pattern 136b may be electrically connected to a plurality of first conductive layer patterns 136a facing the third and fourth sidewalls of the first active patterns 108. Thus, both of the first conductive layer pattern 136a and the second conductive layer pattern 136b included in the conductive liner structure 136 may be electrically connected to each other.

When a voltage is applied through the second conductive layer pattern 136b, the voltage may be applied to the first conductive layer patterns 136a facing on the third and fourth sidewalls of the first active patterns 108 arranged in each of the first and second directions X and Y.

In some example embodiments, a portion or entirety of the first insulation layer pattern 106a exposed on the sidewall of the first opening 130a may be additionally etched. The first insulation layer pattern 106a exposed by the sidewall of the first opening 130a may serve as a portion of a gate insulation layer. An amount of etching of the first insulation layer pattern 106a may be controlled according to a target stack structure of the gate insulation layer.

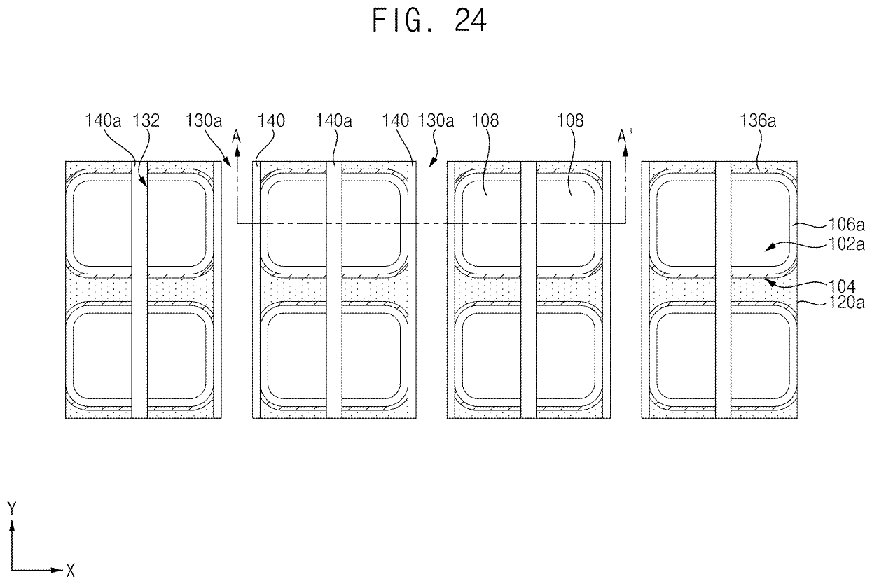

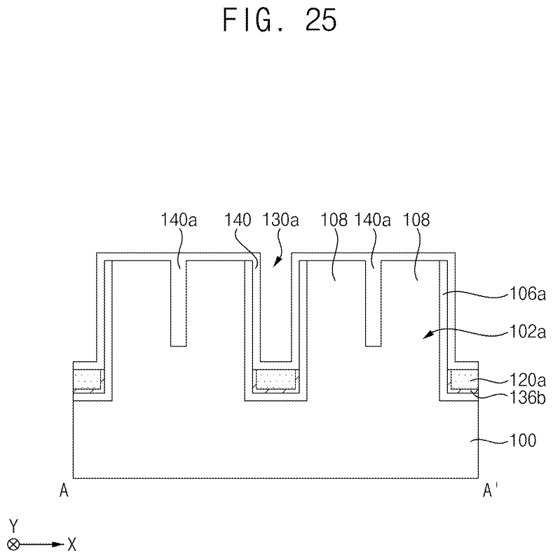

Referring to FIGS. 24 and 25, the third insulation layer 140 may be formed on the surfaces of the first active patterns 108, the first opening 130a, and the second opening 132. The third insulation layer 140 may be conformally formed on the surface of the first opening 130a, and may completely fill the second opening 132. After forming the third insulation layer 140, an inner space of the first opening 130a may remain.

The third insulation layer 140 may include, e.g., silicon oxide. The third insulation layer 140 may be formed by an atomic layer deposition process or a chemical vapor deposition process. A portion of the third insulation layer completely filling the second opening 132 may define the separation layer pattern 140a.

The third insulation layer 140 formed on an inner surface of the first opening 130a may serve as a portion of the gate insulation layer. That is, the first insulation layer pattern 106a and the third insulation layer 140 formed on the sidewall of the first active pattern 108 in the first opening 130a may be used as the gate insulation layer.

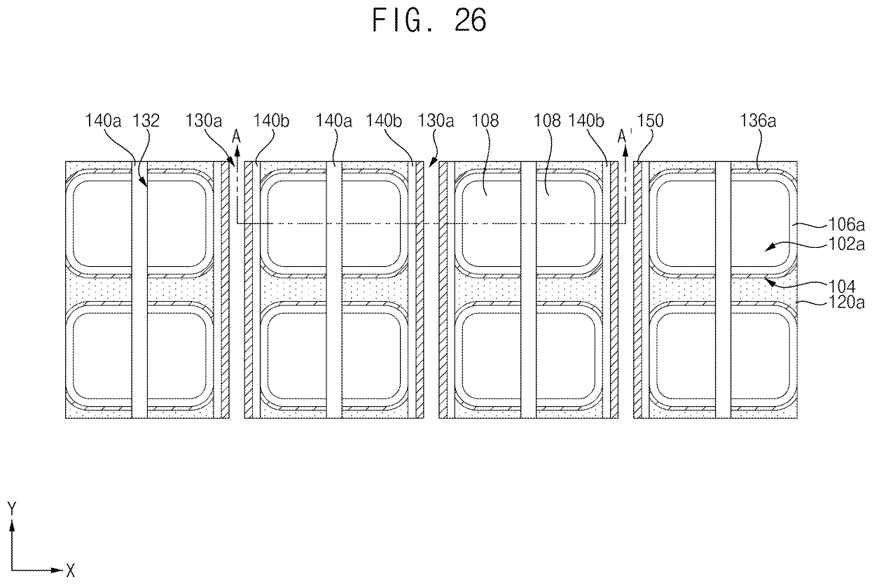

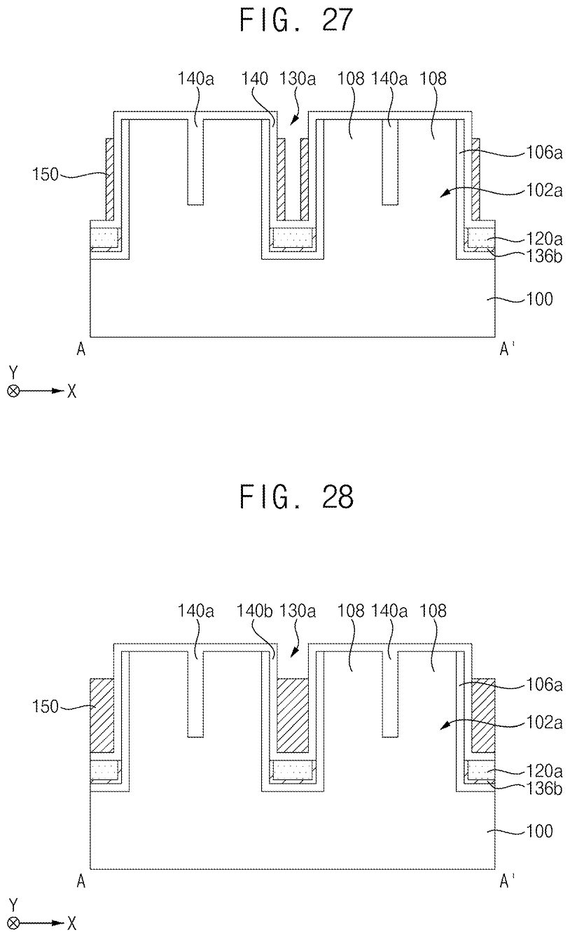

Referring to FIGS. 26 and 27, a gate conductive layer may be formed on the surface of the third insulation layer 140. After forming the gate conductive layer, an inner space of the first opening 130a may remain.

The gate conductive layer may include a metal, e.g., titanium, titanium nitride, tantalum, tantalum nitride, tungsten, tungsten nitride, tungsten carbonitride, or the like. In example embodiments, the gate conductive layer may be formed by an atomic layer deposition process. In some example embodiments, the gate conductive layer may include polysilicon.

The gate conductive layer may be anisotropically etched to form the gate pattern 150 on the sidewall of the first opening 130a. In the etching process, the gate conductive layer formed on the upper surface of the first active pattern 108 and the gate conductive layer formed on the third insulation layer 140 on the lower surface of the first opening 130a may be completely removed. In addition, a portion of the gate conductive layer formed on the upper sidewall of the first opening 130a may be removed. Accordingly, a top surface of the gate pattern 150 may be lower than a top surface of the first active pattern 108.

As shown in FIG. 3, the first insulation layer pattern 106a and the first conductive layer pattern 136a may cover both sidewalls of the first active pattern 108 in the second direction Y. Accordingly, the top surface of the gate pattern 150 may be lower than the top surface of the first conductive layer pattern 136a on the third and fourth sidewalls of the first active pattern 108.

The gate pattern 150 may extend in the second direction Y along the sidewall of the first opening 130a. Two separated gate patterns 150 may be disposed on sidewalls of the first opening 130a, respectively. The two separated gate patterns 150 may be disposed in the first opening 130a. Each of the gate patterns 150 may serve as a word line.

The first insulation layer pattern 106a, the third insulation layer 140, and the gate pattern 150 may be laterally stacked on the first sidewall of each of the first active patterns 108.

A lower portion of the first active pattern 108 may serve as the first source/drain region, and an upper portion of the first active pattern 108 may serve as the second source/drain region. The first active pattern 108 between the first and second source/drain regions may serve as a channel region. A surface of the first active pattern 108 facing the gate pattern 150 may serve as the channel region. Accordingly, the first active pattern 108, the first insulation layer pattern 106a, the third insulation layer 140, and the gate pattern 150 may serve as the vertical channel transistor. A plurality of vertical channel transistors commonly using the gate pattern 150 may be formed on sidewalls of the first active patterns 108 arranged in the second direction Y.

As described above, the plurality of vertical channel transistors may further include the conductive liner structure 136 including the first and second conductive layer patterns 136a and 136b. The first insulation layer pattern 106a and the first conductive layer pattern 136a may cover the third and fourth sidewalls of each of the first active patterns 108. The first conductive layer pattern 136a may partially surround the first active pattern 108 to be spaced apart from the first active pattern 108. The first conductive layer pattern 136a may not contact the gate pattern 150. The first conductive layer pattern 136a may contact the third insulation layer 140 serving as the gate insulation layer.

The second conductive layer patterns 136b may be electrically connected to a lower portion of the first conductive layer pattern 136a, and a voltage may be applied to the first conductive layer patterns 136a through the second conductive layer pattern 136b. When the voltage is applied to the first conductive layer patterns 136a, a body voltage may be applied to the first active patterns 108. Accordingly, a threshold voltage of the vertical channel transistor may be controlled by the body voltage.

Referring to FIGS. 1 to 3 again, a filling insulation layer may be formed to cover the third insulation layer 140 and the gate pattern 150. The filling insulation layer may be planarized to form the filling insulation pattern 154 in the first opening 130a. The filling insulation pattern 154 may include, e.g., silicon oxide. An upper surface of the first active pattern 108 may be exposed by the planarization process.

By the above process, the semiconductor device as described with reference to FIGS. 1 to 5 may be manufactured.

In some example embodiments, as shown in FIG. 28, a gate conductive layer may be formed to fill the first opening 130a, and the gate conductive layer may be etched back to form the gate pattern 150a filling the first opening 130a. Thereafter, the filling insulation pattern 154 may be formed to cover the third insulation layer 140 and the gate pattern 150a. Accordingly, the semiconductor device as described with reference to FIGS. 8 and 9 may be manufactured.

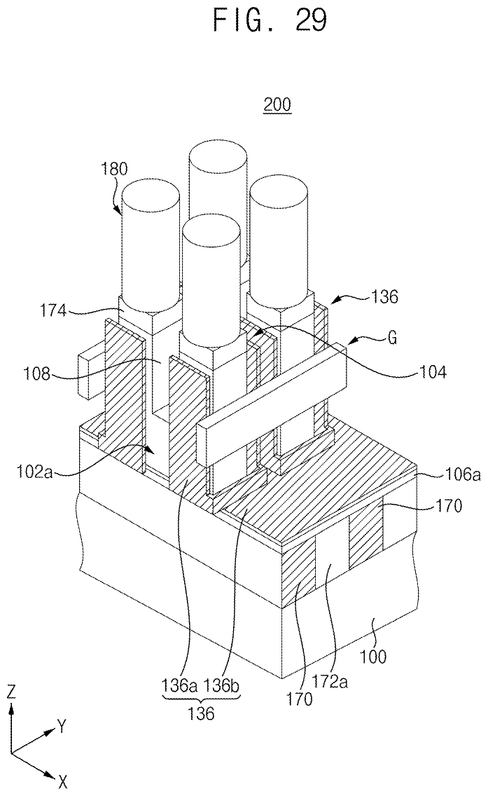

FIG. 29 is a perspective view illustrating a semiconductor device according to example embodiments.

Referring to FIG. 29, a semiconductor device 200 may include a bit line 170, the active structure 102a including the first active patterns 108, the gate structure G, the conductive liner structure 136, and a capacitor 180 on the substrate 100. For example, the semiconductor device may be a dynamic random access memory (DRAM) device including a vertical channel transistor (VCT). In the vertical channel transistor, the first active pattern 108 may extend in the vertical direction Z perpendicular to the upper surface of the substrate 100.

The bit lines 170 may be formed on the substrate 100. The bit lines 170 extend in the first direction X, and may be spaced apart from each other in the second direction Y. In example embodiments, a lower insulation layer may be disposed on the substrate 100 to cover the substrate 100. Accordingly, the lower insulation layer may be formed between the substrate 100 and the bit line 170.

A lower insulation pattern 172a may be formed on the substrate 100 to fill a space between the bit lines 170. The lower insulation pattern 172a may extend in the first direction X.

The bit lines 170 may include a semiconductor material doped with impurities. In example embodiments, the bit lines 170 may be formed by etching an initial substrate. For example, the bit lines 170 may include silicon doped with impurities. An upper surface of the bit line 170 and an upper surface of the lower insulation pattern 172a may be coplanar with each other.

An active structure 102a may be formed on the bit line 170, and the active structure 102a may contact the bit line 170. The active structures 102a may be regularly arranged in each of the first and second directions X and Y.

The plurality of active structures 102a disposed on one of bit lines 170 may be spaced apart from each other in the first direction X. Also, the plurality of active structures 102a disposed on different bit lines 170 may be spaced apart from each other in the second direction Y. In order to avoid the complexity of the drawing, only two active structures spaced apart in the second direction Y are shown in FIG. 29, but more active structures may be disposed in the first direction X and the second direction Y.

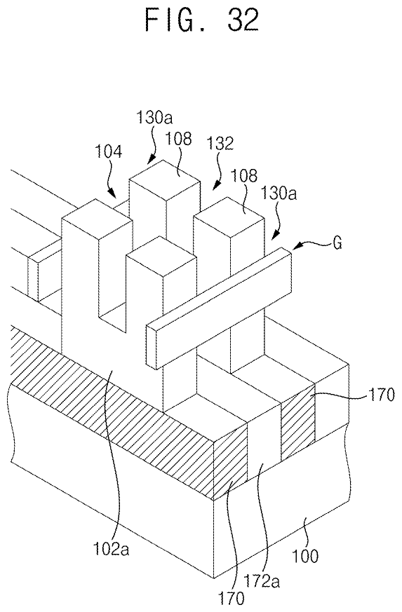

A second opening 132 (referred to FIG. 32) may be formed in a center portion in the first direction X of the active structure 102a. Accordingly, the active structure 102a may include two first active patterns 108 between the second opening 132, and the two active patterns 108 may include each of both sides of the second opening 132. Each of the first active patterns 108 may have a pillar shape. Lower portions of the first active patterns 108 may be connected to each other. The second opening 132 may extend in the second direction Y. A third insulation layer may fill the second opening 132.

The first opening 130a (referred to FIG. 32) may be disposed between the active structures 102a spacing apart from each other in the first direction X. The first opening 130a may extend in the second direction Y.

The gate structure G may be formed on the active structure 102a, and the conductive liner structure 136 may be spaced apart from the active structure 102a. The gate structure G and the conductive liner structure 136 may be substantially the same as the gate structure G and the conductive liner structure 136 described with reference to FIGS. 1 to 5, respectively.

As described with reference to FIGS. 1 to 5, an insulation layer and/or insulation layer patterns may be further formed on the active structure 102a. An insulating interlayer may cover the gate structure G, the conductive liner structure 136, and the first active patterns.

Capacitor contacts 174 may pass through the insulating interlayer. The capacitor contacts 174 may contact the first active patterns 108, respectively. The capacitor contact 174 may include, e.g., doped polysilicon, Al, Cu, Ti, Ta, Ru, W, Mo, Pt, Ni, Co, TiN, TaN, WN, NON, TiAl, TiAlN, TiSi, TiSiN, TaSi, TaSiN, RuTiN, NiSi, CoSi, IrOx, RuOx, or a combination thereof.

An etch stop layer may be formed on the insulating interlayer, and a capacitor 180 may contact the capacitor contact 174 through the etch stop layer. The capacitor 180 may include a lower electrode, a dielectric layer, and an upper electrode. In example embodiments, a landing pad may be further formed between the capacitor contact 174 and the lower electrode.

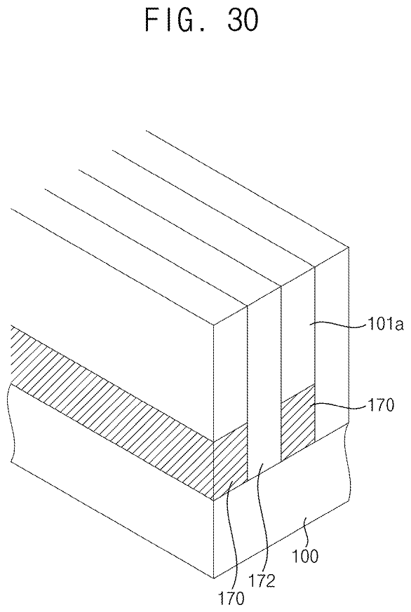

FIGS. 30 to 33 are perspective views illustrating stages in a method of manufacturing a semiconductor device according to example embodiments.

Referring to FIG. 30, an initial substrate may be implanted with impurities to form a preliminary bit line region. In example embodiments, the impurities may be doped into a region spaced downwardly from the upper surface of the initial substrate.

The initial substrate may be anisotropically etched to form structures extending in the first direction X and in which the bit line 170 and the first preliminary active structure 101a are stacked. Trenches extending in the first direction X may be formed between the structures. A bottom of the trench may be the same plane as a surface of the preliminary bit line region, or the bottom of the trench may be lower than a bottom surface of the preliminary bit line region. Accordingly, the preliminary bit line region may be separated by the trench to form the bit line 170. The first preliminary active structure 101a may be formed on the bit line 170. A preliminary lower insulation layer 172 may be formed to fill the trench.

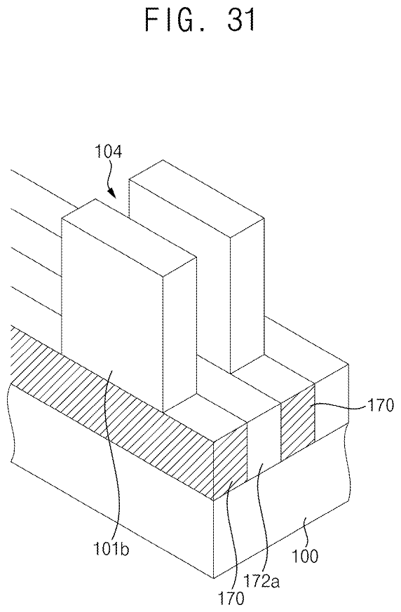

Referring to FIG. 31, the preliminary lower insulation layer 172 and the first preliminary active structure 101a may be etched to form the lower insulation pattern 172a and a second preliminary active structure 101b.

The second preliminary active structure 101b may be spaced apart from each other in the first and second directions X and Y. The second preliminary active structure 101b may be regularly arranged in the first and second directions X and Y. The first trench 104 may be formed between the second preliminary active structures 101b. An upper surface of the bit line 170 may be exposed by the bottom of the first trench 104. The arrangement of the second preliminary active structures 101b may be substantially the same as an arrangement of the preliminary active structures described with reference to FIGS. 10 and 11.

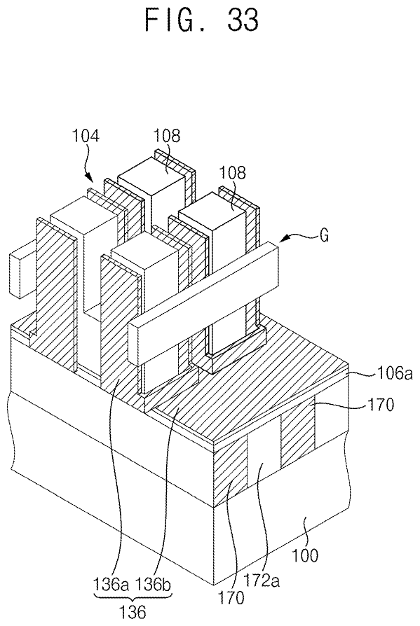

Referring to FIG. 33, the processes as described with reference to FIGS. 12 to 27 may be performed on the second preliminary active structure 101b. Accordingly, as shown in FIG. 27, the vertical channel transistor including the gate structure and the first conductive liner structure 136 may be formed on the first active pattern 108.

A first insulating interlayer may be formed to fill the vertical channel transistor. The first insulating interlayer may include, e.g., silicon oxide. An etch stop layer may be formed on the first insulating interlayer.

Referring to FIG. 29 again, capacitor contacts 174 may be formed through the first insulating interlayer and the first etch stop layer. The capacitor contacts 174 may contact upper portions of the first active patterns 108, respectively. A capacitor 176 may be formed on the capacitor contact 174.

By the above process, a DRAM device may be manufactured.

By way of summation and review, as the semiconductor device is highly integrated, it may not be easy to control a threshold voltage of a vertical channel transistor. Therefore, example embodiments provide a semiconductor device having improved threshold voltage control of the vertical channel transistor.

That is, in the semiconductor device according to example embodiments, the vertical channel transistor may include first conductive layer patterns spaced apart from the first active pattern and facing a portion of the sidewall of the first active pattern. A threshold voltage of the vertical channel transistor may be controlled by applying a voltage to the first conductive layer patterns for inducing electric fields in the first active pattern. Accordingly, the semiconductor device may have excellent electrical characteristics.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate;
a first active pattern protruding from the substrate;
a gate structure including a gate insulation layer and a gate pattern laterally stacked on a first sidewall of the first active pattern, the gate pattern facing the first sidewall of the first active pattern and extending in a first direction parallel to an upper surface of the substrate; and
first conductive patterns contacting the gate insulation layer and protruding beyond a sidewall of the gate structure, the first conductive patterns facing second and third sidewalls in the first direction of the first active pattern, and the first conductive patterns being spaced apart from the first active pattern.

2. The semiconductor device as claimed in claim 1, wherein a top surface of the gate structure is lower than a top surface of the first active pattern.

3. The semiconductor device as claimed in claim 1, wherein a top surface of the gate structure is lower than a top surface of the first conductive layer pattern.

4. The semiconductor device as claimed in claim 1, further comprising a second conductive layer pattern spaced apart from a bottom of the gate structure, the second conductive layer pattern being under a bottom of the gate structure, and the second conductive layer pattern being electrically connected to lower portions of the first conductive layer patterns.

5. The semiconductor device as claimed in claim 4, wherein the first conductive layer patterns and the second conductive layer pattern include a same metal.

6. The semiconductor device as claimed in claim 1, wherein the first conductive layer patterns include titanium, titanium nitride, tantalum, tantalum nitride, tungsten, tungsten nitride, or tungsten carbonitride.

7. The semiconductor device as claimed in claim 1, further comprising an insulation layer between the first conductive layer patterns and the first active pattern, the gate insulation layer being positioned between the first conductive layer patterns and the gate pattern.

8. A semiconductor device, comprising:
a substrate;
first active patterns protruding from the substrate and arranged in a first direction and a second direction parallel to an upper surface of the substrate and perpendicular to each other, the first active patterns being spaced apart from each other;
a gate structure on first sidewalls of the first active patterns, the gate structure extending in the second direction to face the first sidewalls of the first active patterns;
a separation pattern filling an opening between second sidewalls of the first active patterns, the second sidewalls facing the first sidewalls; and
a conductive liner structure protruding beyond a sidewall of the gate structure, the conductive liner structure being spaced apart from the first active patterns, and the conductive liner structure facing each of third and fourth sidewalls in the second direction of the first active patterns,
wherein the conductive liner structure includes:
first conductive layer patterns facing the third and fourth sidewalls of each of the first active patterns, and being spaced apart from the first active patterns; and
a second conductive layer pattern electrically connected to lower portions of the first conductive layer patterns.

9. The semiconductor device as claimed in claim 8, wherein the gate structure includes a gate insulation layer and a gate pattern laterally stacked on the first sidewalls of the first active patterns.

10. The semiconductor device as claimed in claim 9, wherein the conductive liner structure is spaced apart from the gate pattern.

11. The semiconductor device as claimed in claim 9, wherein the gate insulation layer and the separation pattern include a same material.

12. The semiconductor device as claimed in claim 9, wherein the conductive liner structure is spaced apart from the first active patterns.

13. The semiconductor device as claimed in claim 12, further comprising an insulation layer between the conductive liner structure and the first active patterns.

14. The semiconductor device as claimed in claim 8, wherein the first conductive layer patterns includes titanium, titanium nitride, tantalum, tantalum nitride, tungsten, tungsten nitride, or tungsten carbonitride.

15. The semiconductor device as claimed in claim 8, wherein a top surface of the gate structure is lower than a top surface of each of the first conductive layer patterns.

16. The semiconductor device as claimed in claim 8, wherein the separation pattern extends in the second direction.

17. The vertical semiconductor device as claimed in claim 8, further comprising:
a bit line electrically connected to lower portions of the first active patterns, the bit line extending in the first direction; and
a capacitor on each of the first active patterns, the capacitor being electrically connected to each of the first active patterns.

18. A vertical semiconductor device, comprising:
a substrate;
first active patterns protruding from the substrate, the first active patterns being arranged in a first direction and a second direction parallel to an upper surface of the substrate and perpendicular to each other, and the first active patterns being spaced apart from each other;
a gate structure on first sidewalls of the first active patterns, the gate structure extending in the second direction to face the first sidewalls of the first active patterns, and the gate structure including a gate insulation layer and a gate pattern; and
a conductive liner structure facing each of second and third sidewalls in the second direction of the first active patterns, the conductive liner structure being spaced apart from the gate pattern and the first active patterns.

19. The vertical semiconductor device as claimed in claim 18, further comprising a separation pattern filling an opening between fourth sidewalls facing the first sidewall of each of the first active patterns, and the separation pattern extending in the second direction, the separation pattern and the gate insulation layer including a same material.

20. The vertical semiconductor device as claimed in claim 18, wherein the first conductive liner structure includes:
first conductive layer patterns facing the second and third sidewalls in the second direction of each of the first active patterns, and being spaced apart from the first active patterns; and
a second conductive layer pattern electrically connected to lower portions of the first conductive layer patterns.
